(19) United States
(12) Patent Application Publication
(10) Pub. No.: US 2025/0153744 A1
(43) Pub. Date: May 15, 2025

(54) Transport Vehicle

(71) Applicant: Daifuku Co., Ltd., Osaka-shi (JP)

(72) Inventors: Kosuke Mishima, Hinocho (JP); Shigekichi Ito, Hinocho (JP); Hirokatsu Kashikura, Hinocho (JP)

(21) Appl. No.: 18/941,255

(22) Filed: Nov. 8, 2024

(30) Foreign Application Priority Data
Nov. 9, 2023 (JP) 2023-191525

(51) Int. Cl. B61B 3/02; B65G 1/04

(52) U.S. Cl. CPC B61B 3/02; B65G 1/0464

(57) ABSTRACT

A transport vehicle for transporting an article includes a travel unit configured to travel; a vehicle body including a storage section configured to store the article; and an information communication unit. The vehicle body includes a first wall portion facing the storage section from a first side in a travel direction; and a first bumper section disposed to project toward the first side in the travel direction from the first wall portion. The information communication unit includes a sensor configured to detect motion of the vehicle body; a communications device configured to communicate with at least the travel unit; and a recording device configured to store detection data from the sensor and acquisition data acquired by the communications device.

### CROSS-REFERENCE TO RELATED APPLICATION

This application claims priority to Japanese Patent Application No. 2023-191525 filed Nov. 9, 2023, the disclosure of which is hereby incorporated by reference in its entirety.

### BACKGROUND OF THE INVENTION

### 1. Field of the Invention

The present invention relates to a transport vehicle.

### 2. Description of Related Art

For example, Japanese Unexamined Patent Application Publication No. 2022-003858 (JP 2022-003858) discloses a technology related to a transport vehicle. Hereinafter, reference signs described within parentheses in the Description of the Related Art are reference signs used in JP 2022-003858.

A transport facility (100) in JP 2022-003858 includes a traveling rail (2) disposed along a travel path (1), and a transport vehicle (an article transport vehicle 3) configured to travel along the travel path (1). The transport facility (100) is also provided with a plurality of article processing units (P) along the travel path (1). The transport vehicle includes a travel unit (9) guided by the traveling rail (2) to travel, and a vehicle body (a transport vehicle body 10) held by the travel unit (9) from above. The vehicle body includes an article support configured to support an article in a suspended manner, and an actuator configured to lift and lower the article support. The transport vehicle travels on the travel path (1) and transports an article to the plurality of article processing units (P) by lifting and lowering the article support.

In the meantime, in the transport vehicle as described in JP 2022-003858, in order to transport an article appropriately, it is desirable to grasp vehicle information on the state of the travel unit, the motion of the vehicle body (for example, vibration or the like), or the like during transport. In view this, it is conceivable to provide the transport vehicle with a sensor for detecting the state of the travel unit, the motion of the vehicle body, or the like, a recording device for storing a detection result, or the like, for example. However, in a case where the number of transport vehicles is large, when all the transport vehicles are equipped with a device such as the sensor or the recording device described above, there is a problem that the cost greatly increases. In the meantime, in a case where such a device is attached to only some transport vehicles, a difference in configuration between the transport vehicles due to the presence or absence of the device causes such a problem that a transport-vehicle assembling process becomes complicated or maintainability decreases.

### SUMMARY OF THE INVENTION

In view of the foregoing, it is desirable to provide a technology that can appropriately acquire vehicle information on a transport vehicle with a configuration that attains easy assembly and a high maintainability.

A transport vehicle according to this disclosure is a transport vehicle for transporting an article and includes: a travel unit configured to travel; a vehicle body held by the travel unit and including a storage section configured to store the article; and an information communication unit. The vehicle body includes: a first wall portion facing the storage section from a first side in a travel direction of the travel unit which first side is one side in the travel direction; and a first bumper section disposed to project toward the first side in the travel direction from the first wall portion. The information communication unit includes: a sensor configured to detect motion of the vehicle body; a communications device configured to communicate with at least the travel unit; and a recording device configured to store detection data from the sensor and acquisition data acquired by the communications device. The information communication unit is detachably attached to the first wall portion and disposed, in the travel direction, between the first wall portion and an end portion of the first bumper section which end portion is on the first side in the travel direction.

In this configuration, since the transport vehicle includes the information communication unit, the transport vehicle can acquire vehicle information on the motion of the vehicle body, the state of the travel unit, or the like as data as needed and store the vehicle information. Accordingly, it is possible to easily collect the vehicle information on the transport vehicle.

In addition, in this configuration, since such an information communication unit is detachably attached to the first wall portion for which an operator relatively easily performs work, it is selectable whether or not the information communication unit is attached to the transport vehicle, and it is also possible to reduce differences between transport vehicles in terms of components to be used in a manufacturing process of the transport vehicles and in terms of components constituting the transport vehicles, depending on whether or not the transport vehicles include the information communication unit. In addition, it is possible to easily attach the information communication unit to the transport vehicle after the use of the transport vehicle is started, and in a case where the information communication unit has a malfunction or the like, it is also possible to easily detach the information communication unit. This accordingly makes it possible to improve maintainability of the transport vehicle.

Besides, in this configuration, the information communication unit is disposed inward of (closer to the first wall portion than) the end portion of the first bumper section which end portion is on the first side in the travel direction. This accordingly makes it possible to protect the information communication unit from impact or the like.

Further features and advantages of the transport vehicle are made clear from the following description on exemplary and nonlimiting embodiments to be described with reference to the drawings.

### BRIEF DESCRIPTION OF THE DRAWINGS

FIG. 1 is a front view of a transport vehicle;

FIG. 2 is a side view of the transport vehicle;

FIG. 3 is a control block diagram;

FIG. 4 is a plan view illustrating the arrangement of an information communication unit, a first bumper section, and a first wall portion;

FIG. 5 is a front view illustrating the arrangement of the information communication unit, the first bumper section, and the first wall portion; and

FIG. 6 is a side view illustrating the arrangement of the information communication unit, the first bumper section, and the first wall portion.

### DESCRIPTION OF THE INVENTION

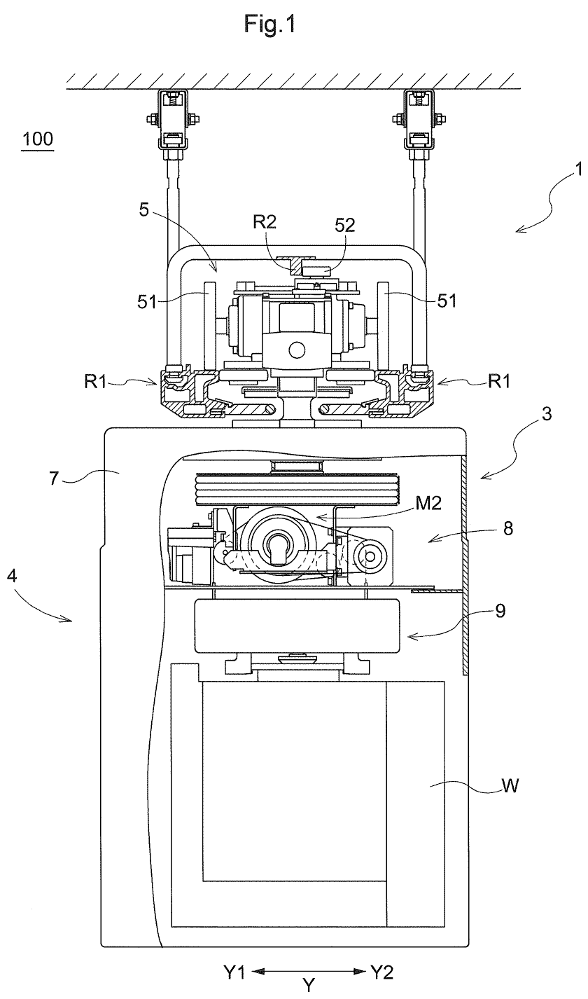

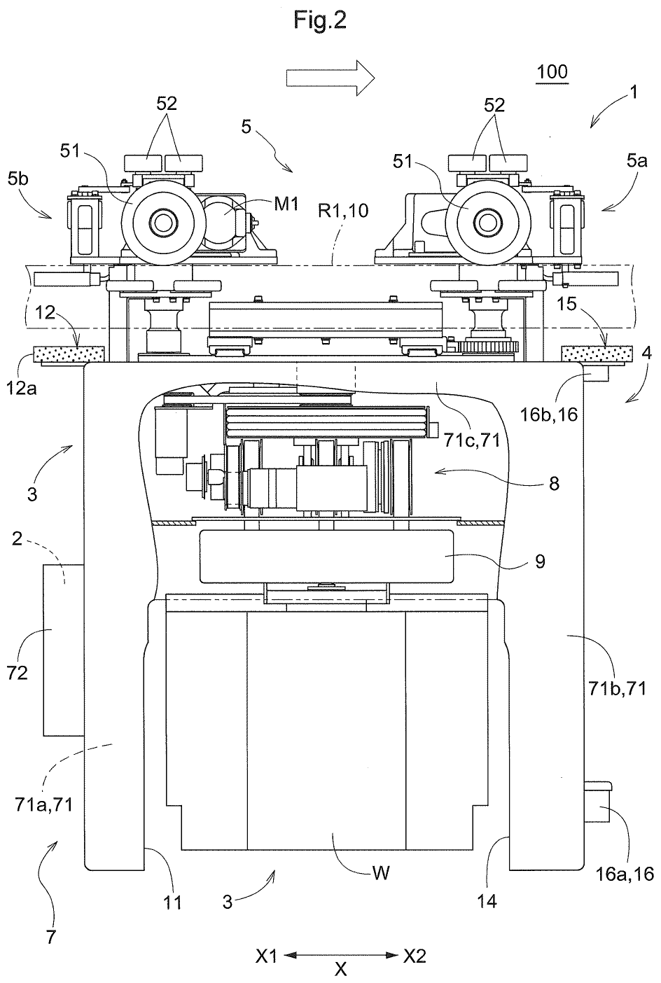

The following will describe embodiments of a transport vehicle with reference to the drawings. As illustrated in FIGS. 1, 2, a transport vehicle 1 transports an article W. In the present embodiment, the transport vehicle 1 is configured to travel along a predetermined travel path 10 in a transport facility 100 and transport the article W. In the present example, the article W is a container (FOUP: Front Opening Unified Pod) for storing a semiconductor substrate. The transport vehicle 1 transports the article W to a processing device configured to perform processing on a semiconductor substrate. The transport vehicle 1 may also transport the article W to a storage shelf or the like for storing the article W. Note that the article W may be a reticle storage container (so-called reticle pod) for storing a reticle, or the like, other than the FOUP. In the transport facility 100 of the present embodiment, a plurality of transport vehicles 1 is configured to transport the article W.

As illustrated in FIGS. 1, 2, the transport vehicle 1 includes a travel unit 5 configured to travel, a vehicle body 4 held by the travel unit 5 and including a storage section 3 configured to store the article W, and an information communication unit 2.

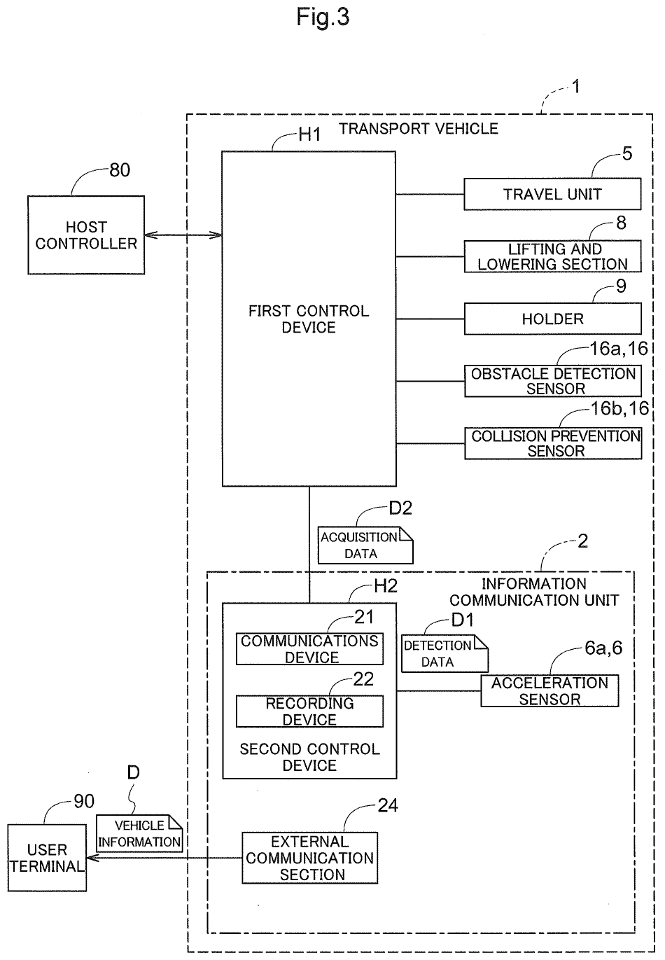

The transport vehicle 1 further includes a first control device H1 (FIG. 3). In the present embodiment, the travel unit 5 travels along the travel path 10. Note that, in the following description, a travel-direction first side X1 indicates one side in a travel direction X of the travel unit 5, and a travel-direction second side X2 indicates a side reverse to the travel-direction first side X1 in the travel direction X. In the meantime, a width direction Y indicates a direction perpendicular to the travel direction X as viewed vertically, and a width-direction first side Y1 indicates one side in the width direction Y, and a width-direction second side Y2 indicates a direction reverse to the width-direction first side Y1.

In the present embodiment, as illustrated in FIG. 2, the travel-direction second side X2 is on a front side in the travel direction X. More specifically, the travel unit 5 travels along the travel path 10 from the travel-direction first side X1 toward the travel-direction second side X2. Accordingly, the travel-direction second side X2 is a travel-direction front side of the travel unit 5 (the transport vehicle 1), and the travel-direction first side X1 is a travel-direction rear side of the travel unit 5 (the transport vehicle 1).

As illustrated in FIGS. 1, 2, the travel unit 5 includes a plurality of wheels 51. The wheels 51 roll on a traveling rail R1 (herein, a pair of traveling rails R1) provided along the travel path 10. The travel unit 5 also includes a drive motor M1 for driving the wheels 51. The travel unit 5 travels along the traveling rail R1 in response to at least one of the plurality of wheels 51 being rotated by the drive motor M1. In the present example, the traveling rail R1 is supported on a ceiling in a suspended manner, and the travel path 10 is formed on the ceiling. That is, in the present example, the transport vehicle 1 is an overhead transport vehicle. Note that the transport vehicle 1 may be a transport vehicle other than the overhead transport vehicle (for example, a transport vehicle configured to travel autonomously on a floor surface, a transport vehicle configured to travel by being guided by a rail or the like provided on the floor surface, an automatic sorting wagon configured to travel in an automated warehouse and sort the article W, a stacker crane, or the like).

In the present example, the travel unit 5 includes a plurality of guide wheels 52. The guide wheels 52 abut with a guide rail R2 supported on the ceiling in a suspended manner. The guide rail R2 is disposed in a branching section or a merging section of the travel path 10. The guide wheels 52 are movable between a right guiding position at which the guide wheels 52 abut with the guide rail R2 from the right side and a left guiding position at which the guide wheels 52 abut with the guide rail R2 from the left side. The travel unit 5 travels on a given travel path 10 at the branching section or the merging section such that the guide wheels 52 are moved to either of the right guiding position and the left guiding position. The travel unit 5 is configured to hold the vehicle body 4 in a suspended manner. In the example of FIG. 2, the travel unit 5 includes a first travel unit 5a and a second travel unit 5b separated from each other in the travel direction X. The first travel unit 5a is disposed on the front side (the travel-direction second side X2) relative to the second travel unit 5b. Each of the first travel unit 5a and the second travel unit 5b includes a plurality of wheels 51 and a plurality of guide wheels 52. The first travel unit 5a and the second travel unit 5b both hold a single vehicle body 4 in a suspended manner. Note that, in a case where the transport vehicle 1 is a vehicle other than the overhead transport vehicle, the travel unit 5 may be a wagon unit configured to support the wheels 51 or the like and also support the vehicle body 4 from below.

The vehicle body 4 is held by the travel unit 5 in a suspended manner. In the present example, the vehicle body 4 is disposed below the traveling rail R1 (below the travel unit 5 across the traveling rail R1). The vehicle body 4 holds the article W and transfers the article W to a transport place. In the present embodiment, the vehicle body 4 includes a holder 9 configured to hold the article W. The holder 9 holds the article W in a suspended manner. The holder 9 is also configured to be liftable and lowerable relative to the travel unit 5. While the travel unit 5 is traveling, the holder 9 is placed at a lifted position. In the meantime, in a case where the article W is transferred to a transport place, the holder 9 is placed at a lowered position. The lifted position is a position where the article W held by the holder 9 is stored in the storage section 3. In the meantime, the lowered position is a position lower than the lifted position, and the holder 9 receives the article W put on the transport place or delivers the article W to the transport place at the lowered position. In the present example, the vehicle body 4 includes a lifting and lowering section 8. The lifting and lowering section 8 includes a drum, a belt wound on the drum and having a distal end coupled with the holder 9, and a lifting and lowering motor M2 (FIG. 1) configured to rotate the drum to drive the belt. The lifting and lowering section 8 causes the lifting and lowering motor M2 to rotate the drum in such a manner as to lift and lower the holder 9 between the lifted position and the lowered position as described above.

As illustrated in FIG. 2, the vehicle body 4 includes a first wall portion 11 facing the storage section 3 from the travel-direction first side X1, and a first bumper section 12 disposed to project toward the travel-direction first side X1 from the first wall portion 11. The vehicle body 4 also includes a second wall portion 14 facing the storage section 3 from the travel-direction second side X2, and a second bumper section 15 disposed to project toward the travel-direction second side X2 from the second wall portion 14. The first wall portion 11 and the second wall portion 14 are disposed to overlap with the article W stored in the storage section 3 as viewed in the travel direction X.

As illustrated in FIGS. 1, 2, and 4, the vehicle body 4 includes a cover section 7. The cover section 7 is provided to cover the storage section 3 from the travel direction X and from above. The cover section 7 is provided also to cover the lifting and lowering section 8 and the holder 9 at the lifted position. In the present example, the cover section 7 is disposed below the traveling rail R1.

The cover section 7 includes a cover main body 71 and a unit cover 72. The unit cover 72 is configured to be attachable to and detachable from the cover main body 71. The cover main body 71 includes a first cover section 71a, a second cover section 71b, and a connecting section 71c connecting the first cover section 71a to the second cover section 71b. The first cover section 71a is disposed to cover the storage section 3 from the travel-direction first side X1. The second cover section 71b is disposed to cover the storage section 3 from the travel-direction second side X2. The connecting section 71c is disposed to cover the storage section 3 (herein, also the lifting and lowering section 8 and the holder 9 at the lifted position) from above. In the example illustrated herein, the connecting section 71c connects an upper end of the first cover section 71a to an upper end of the second cover section 71b.

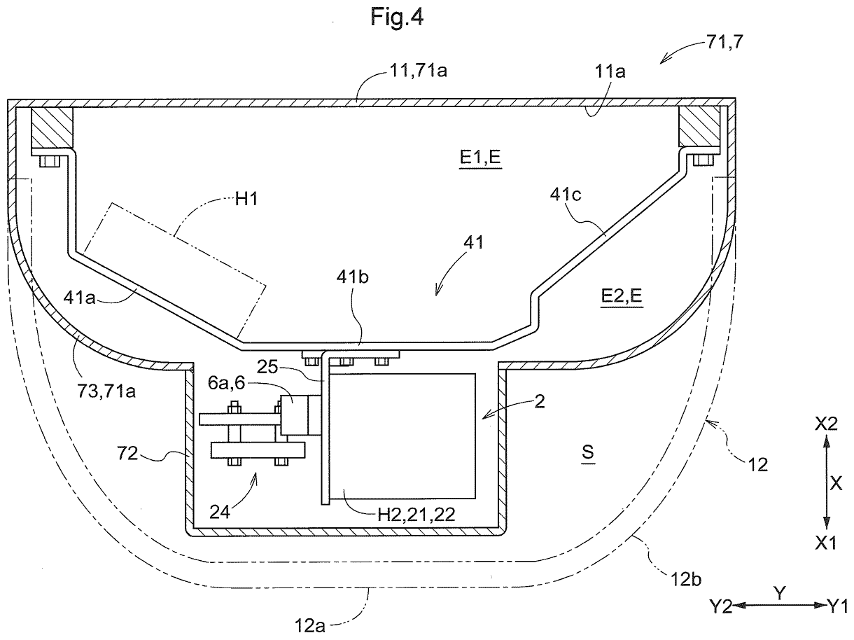

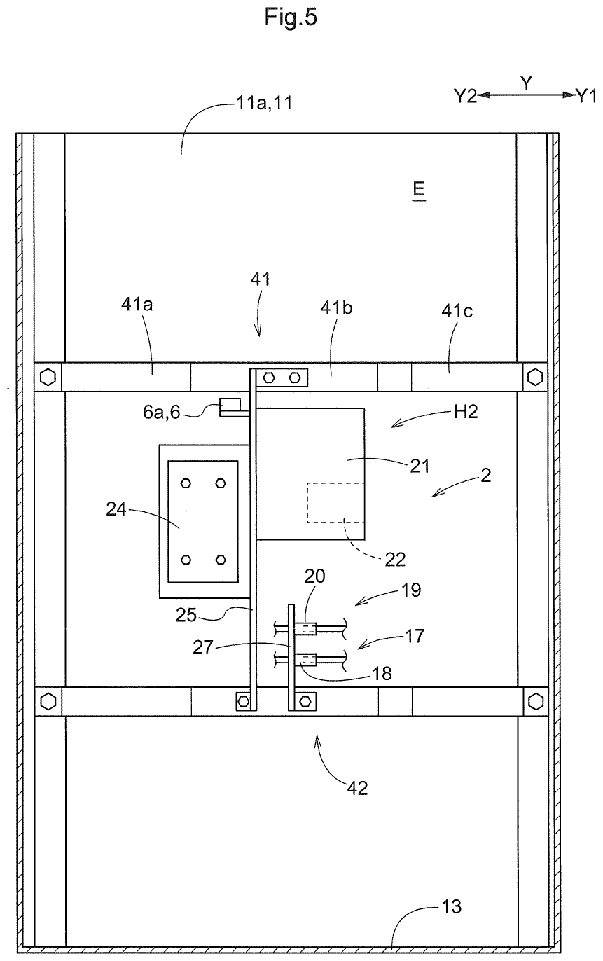

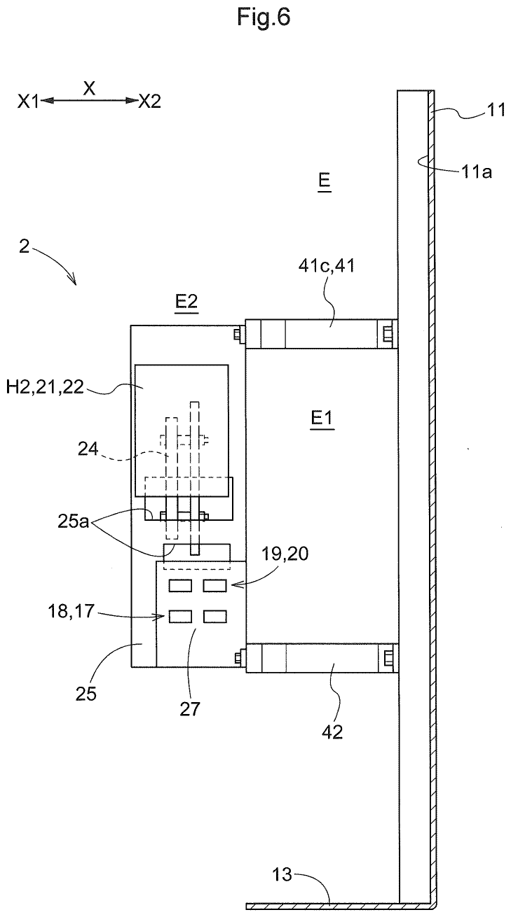

In the preset example, as illustrated in FIG. 4, the first cover section 71a includes the first wall portion 11. The first cover section 71a also includes a vehicle-body cover 73 attachable to and detachable from the first wall portion 11. The vehicle-body cover 73 is disposed to cover the first wall portion 11 from the travel-direction first side X1. In the example of FIGS. 5, 6, the first cover section 71a includes a plate-shape bottom portion 13. The bottom portion 13 connects a lower end of the first wall portion 11 to a lower end of the vehicle-body cover 73. In the present example, the first wall portion 11 is a member (herein, a rectangular member) along an up-down direction and the width direction Y, and when the vehicle-body cover 73 is put on the first wall portion 11, a storage space E is formed between the vehicle-body cover 73 and the first wall portion 11 (FIG. 4). Herein, the unit cover 72 is attachable to and detachable from the vehicle-body cover 73. While the unit cover 72 is put on the vehicle-body cover 73, the storage space E is a space defined by the first cover section 71a, the first wall portion 11, and the bottom portion 13. A region of the vehicle-body cover 73 to which region the unit cover 72 is attached is open (FIG. 4).

In the present example, a bracket 41 is disposed in the storage space E. More specifically, the bracket 41 is provided on a surface 11a of the first wall portion 11 which surface 11a faces the travel-direction first side X1. Herein, the bracket 41 is a belt-shaped member along the width direction Y. As illustrated in FIG. 4, with use of the bracket 41, various types of equipment such as a first control device H1 can be stored in the storage space E, for example.

In the example of FIGS. 4, 5, the bracket 41 includes a first inclined portion 41a, a central portion 41b, and a second inclined portion 41c. The first inclined portion 41a, the central portion 41b, and the second inclined portion 41c are disposed in this order from the width-direction second side Y2 to the width-direction first side Y1. The first inclined portion 41a is fixed to an end portion of the first wall portion 11 which end portion is on the width-direction second side Y2 and is formed to be inclined toward the travel-direction first side X1 as it goes toward the width-direction first side Y1. The central portion 41b is formed continuously with an end portion of the first inclined portion 41a which end portion is on the width-direction first side Y1. Herein, the central portion 41b is disposed in parallel with the first wall portion 11. The second inclined portion 41c is formed continuously with an end portion of the central portion 41b which end portion is on the width-direction first side Y1. The second inclined portion 41c is formed to be inclined toward the travel-direction second side X2 as it goes toward the width-direction first side Y1. An end portion of the second inclined portion 41c which end portion is on the width-direction first side Y1 is fixed to an end portion of the first wall portion 11 which end portion is on the width-direction first side Y1. In the example illustrated herein, the first control device H1 is supported on the first inclined portion 41a and stored in the storage space E.

In the example in FIGS. 4 to 6, the storage space E can be divided into a first storage space E1 on the travel-direction second side X2 relative to the bracket 41 and a second storage space E2 on the travel-direction first side X1 relative to the bracket 41. For example, with use of the bracket 41, equipment can be stored in each of the first storage space E1 and the second storage space E2.

In the preset example, as illustrated in FIG. 2, the second cover section 71b includes the second wall portion 14. In the present embodiment, an obstacle sensor 16 configured to detect an obstacle on the travel-direction second side X2 is attached to the second wall portion 14. Herein, the second wall portion 14 is a member (more specifically, a rectangular member) along the up-down direction and the width direction Y. In the present example, the obstacle sensor 16 attached to the second wall portion 14 includes an obstacle detection sensor 16a and a collision prevention sensor 16b. In the example illustrated herein, the obstacle detection sensor 16a and the collision prevention sensor 16b are separated from each other in the up-down direction. The obstacle detection sensor 16a is configured to detect an obstacle within a range forward of the vehicle body 4 (on the travel-direction second side X2) by a predetermined distance. The collision prevention sensor 16b is configured to detect another transport vehicle 1 traveling ahead in a case where a distance to the another transport vehicle 1 is equal to or less than the predetermined distance. When such a transport vehicle 1 traveling ahead is detected by the collision prevention sensor 16b, a host vehicle (the transport vehicle 1) decelerates or stops. Herein, the obstacle sensor 16 is disposed to project toward the travel-direction second side X2 from the second cover section 71b.

Note that the second cover section 71b may have a configuration similar to that of the first cover section 71a. That is, the second cover section 71b may include the vehicle-body cover 73 covering the second wall portion 14 from the travel-direction second side X2 and the bottom portion 13. In this case, the obstacle sensor 16 may be attached to the second wall portion 14 via the vehicle-body cover 73. The second cover section 71b may not include the vehicle-body cover 73 and the bottom portion 13. Thus, the configuration of the second cover section 71b can be changed appropriately as necessary.

As illustrated in FIGS. 2, 4, the first bumper section 12 is provided in an end portion of the connecting section 71c which end portion is on the travel-direction first side X1. In addition, the first bumper section 12 is attached such that its outer edge (a first-bumper-section outer edge 12b) is disposed outward of the first cover section 71a toward the travel-direction first side X1. In the present example, the first bumper section 12 curves as viewed vertically. More specifically, the first bumper section 12 is a bar-shaped member curving to project toward the travel-direction first side X1 as it goes toward the center of the first bumper section 12 in the width direction Y. The vehicle-body cover 73 and the unit cover 72 are disposed within a region S defined by the first-bumper-section outer edge 12b and the first wall portion 11 as viewed vertically. In the example illustrated herein, the unit cover 72 is disposed, in the travel direction, between the first wall portion 11 and an end portion 12a of the first bumper section 12 on the travel-direction first side X1 as viewed vertically.

As illustrated in FIG. 2, the second bumper section 15 is provided in an end portion of the connecting section 71c which end portion is on the travel-direction second side X2. The second bumper section 15 is disposed such that its position in the up-down direction is the same as that of the first bumper section 12. The second bumper section 15 is attached such that its outer edge is disposed outward of the second cover section 71b toward the travel-direction second side X2. In the present example, the second bumper section 15 curves as viewed vertically. More specifically, the second bumper section 15 is a bar-shaped member curving to project toward the travel-direction second side X2 as it goes toward the center of the second bumper section 15 in the width direction Y. The obstacle sensor 16 is disposed inwardly (on the travel-direction first side X1) from an outer edge of the second bumper section 15.

The information communication unit 2 has a function to acquire vehicle information D on the motion of the vehicle body 4, the state of the travel unit 5, or the like as data and store the vehicle information D. As illustrated in FIG. 3, the information communication unit 2 has a function to transmit the acquired vehicle information D to a user terminal 90 or the like provided externally. As illustrated in FIGS. 4 to 6, the information communication unit 2 is detachably attached to the first wall portion 11. More specifically, the information communication unit 2 is detachably attached to the first wall portion 11 via the bracket 41. Here, the information communication unit 2 is attached to the central portion 41b of the bracket 41 by a fastening member. Accordingly, the information communication unit 2 can be attached to or detached from the central portion 41b in response to the fastening member being put on or off. Note that the information communication unit 2 may be attached to the bracket 41 by a clamping mechanism, an engagement mechanism, or the like or may be directly attached to the first wall portion 11. In the present example, the information communication unit 2 is attached to a portion of the central portion 41b which portion is on the travel-direction first side X1. Accordingly, the information communication unit 2 is disposed in the second storage space E2 on the travel-direction first side X1 relative to the bracket 41.

In the present example, as illustrated in FIG. 4, the information communication unit 2 is covered with the unit cover 72 when the information communication unit 2 is attached to the bracket 41. In the example illustrated herein, when the unit cover 72 is attached to the vehicle-body cover 73, the information communication unit 2 is stored in the first cover section 71a. That is, the information communication unit 2 is disposed, in the travel direction X, between the first wall portion 11 and the end portion 12a of the first bumper section 12 on the travel-direction first side X1. More specifically, the information communication unit 2 is disposed within the region S defined by the first wall portion 11 and the outer edge (the first-bumper-section outer edge 12b) of the first bumper section 12 as viewed vertically. In addition, in the present example, the information communication unit 2 and the unit cover 72 are disposed at a position deviating from the obstacle sensor 16 in the up-down direction. More specifically, the information communication unit 2 and the unit cover 72 are disposed above the obstacle detection sensor 16a and but below the collision prevention sensor 16b and do not overlap with these sensors as viewed in the travel direction X.

Note that the cover section 7 may not necessarily include the unit cover 72. In this case, the information communication unit 2 can be covered with the vehicle-body cover 73 from the travel-direction first side X1. More specifically, it is necessary for a portion of the vehicle-body cover 73 which portion covers at least the information communication unit 2 from the travel-direction first side X1 to be disposed on the travel-direction first side X1 relative to the information communication unit 2.

As illustrated in FIGS. 3 to 6, the information communication unit 2 includes a sensor 6 configured to detect the motion of the vehicle body 4, a communications device 21 configured to communicate with at least the travel unit 5, and a recording device 22 configured to store detection data D1 from the sensor 6 and acquisition data D2 acquired by the communications device 21. In the present embodiment, the information communication unit 2 further includes a second control device H2 and an external communication section 24. The second control device H2 includes the communications device 21 and the recording device 22.

In the present embodiment, the sensor 6 configured to detect the motion of the vehicle body 4 can be one or more sensors 6. Examples of such a sensor 6 include an acceleration sensor 6a (three-axis acceleration sensor) configured to measure accelerations of the vehicle body 4 in the up-down direction, the travel direction X, and the width direction Y, a gyro sensor configured to measure an angular velocity of the vehicle body 4, a temperature sensor configured to measure the temperature of the vehicle body 4, and so on. In the example in FIGS. 3 to 6, the acceleration sensor 6a is provided as the sensor 6.

The communications device 21 is configured be communicable with the lifting and lowering section 8, the holder 9, the obstacle sensor 16 (the obstacle detection sensor 16a, the collision prevention sensor 16b), and the acceleration sensor 6a, in addition to the travel unit 5. As described above, the second control device H2 includes the communications device 21. In the present example, the second control device H2 is communicable with the first control device H1. That is, the second control device H2 is communicable with the travel unit 5, the lifting and lowering section 8, the holder 9, and the obstacle sensor 16 via the first control device H1. The second control device H2 does not directly communicate with a host controller 80. The communications device 21 communicates with the travel unit 5, the lifting and lowering section 8, the holder 9, and the obstacle sensor 16 via the first control device H1 as such but is not limited to this. For example, the communications device 21 may be configured to communicate with the travel unit 5, the lifting and lowering section 8, the holder 9, and the obstacle sensor 16 without the first control device H1. The communications device 21 may be also configured to be directly or indirectly communicable with one or more devices from among the travel unit 5, the lifting and lowering section 8, the holder 9, and the obstacle sensor 16.

Here, as illustrated in FIG. 3, the first control device H1 is configured to control the travel unit 5, the lifting and lowering section 8, the holder 9, and the obstacle sensor 16. The first control device H1 is mutually communicable with the host controller 80 configured to control the whole transport facility 100. As described above, the second control device H2 is communicable with the first control device H1. The second control device H2 is configured to control the acceleration sensor 6a and the external communication section 24. The first control device H1 and the second control device H2 each include a processor such as a microcomputer, a peripheral circuit such as a memory, and so on, for example. When such hardware collaborates with a program executed on a processor of a computer or the like, each function is implemented. Note that, herein, the recording device 22 may be a memory incorporated in the second control device H2 or may be a storage medium attachable to and detachable from the second control device H2, as illustrated in FIG. 5. The recording device 22 may have a communication function to store data in a cloud server or directly transmit data to the host controller 80 to store data therein, for example.

In the present example, the second control device H2 acquires acquisition data D2 from the first control device H1 and stores the acquisition data D2. Examples of the acquisition data D2 include data on respective states of the drive motor M1 of the travel unit 5, the lifting and lowering motor M2 of the lifting and lowering section 8, and a holder motor of the holder 9 (more specifically, current, voltage, rotation speeds of the motors, and the like), data on a state of the obstacle sensor 16 (the obstacle detection sensor 16a, the collision prevention sensor 16b) or a detection result therefrom, data on a communication state between the host controller 80 and the first control device H1, and data on a state (temperature or the like) of the first control device H1. In addition, the second control device H2 acquires detection data D1 on a detection result from the acceleration sensor 6a provided in the information communication unit 2 and store the detection data D1. In the present example, the second control device H2 generates vehicle information D based on data (the detection data D1, the acquisition data D2) thus acquired by the second control device H2 and transmits the vehicle information D to the external communication section 24.

The external communication section 24 is a communication substrate configured to communicate with an external terminal (herein, the user terminal 90). The external communication section 24 transmits the vehicle information D acquired from the second control device H2 to one or more user terminals 90.

As illustrated in FIGS. 3 to 6, in the present embodiment, a power feeding connector 17 including a feed terminal 18 configured to supply electric power to the information communication unit 2 is attached to the first wall portion 11. Further, as illustrated in FIG. 5, the power feeding connector 17 is disposed to face any direction except the upper side. In the present example, the power feeding connector 17 is attached to the first wall portion 11 via a connector plate 27. Here, in addition to the power feeding connector 17, a communication connector 20 including a communication terminal 19 configured to communicate with the first control device H1 is also attached to the first wall portion 11 via the connector plate 27. The power feeding connector 17 and the communication connector 20 are both disposed along a direction (more specifically, the width direction Y) along a horizontal plane. In the present example, the power feeding connector 17 and the communication connector 20 are detachably fixed to the connector plate 27 along the width direction Y. A plurality of power feeding connectors 17 and a plurality of communication connectors 20 can be fixed to the connector plate 27. Wiring lines connected to the power feeding connector 17 and the communication connector 20 can be stored in the second storage space E2 or the first storage space E1. In the example of FIGS. 5, 6, the connector plate 27 is a plate-shaped member extending along the up-down direction and the travel direction X and is attached to the first wall portion 11 via an auxiliary bracket 42. The auxiliary bracket 42 is fixed to the first wall portion 11 in such a manner to be disposed below the bracket 41. Since the auxiliary bracket 42 has the same configuration as the bracket 41, descriptions thereof are omitted.

In the example illustrated herein, the information communication unit 2 includes a support member 25 configured to support the second control device H2, the external communication section 24, and the acceleration sensor 6a. As illustrated in FIGS. 5, 6, the support member 25 is a plate-shaped member extending along the up-down direction and the travel direction X. The support member 25 is detachably attached to the bracket 41. More specifically, the support member 25 is attached to the central portion 41b of the bracket 41 by a fastening member. In the example of FIGS. 5, 6, the support member 25 is also detachably attached to the auxiliary bracket 42, in addition to the bracket 41. The external communication section 24 and the acceleration sensor 6a are attached to a surface of the support member 25 which surface faces the width-direction second side Y2. The second control device H2 is attached to a surface of the support member 25 which surface faces the width-direction first side Y1. The external communication section 24 is communicably connected to the second control device H2 by wired communication or radio communication. The support member 25 has an opening 25a through which a communication wiring line connecting each device in the information communication unit 2 to a device (for example, the first control device H1 or the like) of the vehicle body 4, a power-feeding wiring line, or the like is passed. Herein, the support member 25 overlaps with the connector plate 27 as viewed in the width direction Y.

Thus, in the information communication unit 2 in the present example, the second control device H2, the external communication section 24, and the acceleration sensor 6a are supported by the support member 25. The support member 25 is attached to the bracket 41 (in the example of FIGS. 5, 6, the bracket 41 and the auxiliary bracket 42). Accordingly, only by detaching the support member 25 from the bracket 41 and detaching the wiring lines from the power feeding connector 17 and the communication connector 20, the whole information communication unit 2 can be easily detached from the vehicle body 4, and maintainability can be improved. Besides, pieces of equipment such as various sensors or devices can be provided for the support member 25 as necessary, so that the pieces of equipment can be easily attached in comparison with a case where these pieces of equipment are individually provided for the vehicle body 4.

### Other Embodiments

(1) The above embodiment has described, as an example, the configuration in which the unit cover 72 is disposed, in the travel direction X, between the first wall portion 11 and the end portion 12a of the first bumper section 12 on the travel-direction first side X1 as viewed vertically, but the present invention is not limited to this. The unit cover 72 may be disposed to protrude outwardly (toward the travel-direction first side X1) from the end portion 12a of the first bumper section 12 on the travel-direction first side X1 as viewed vertically. In this case, each of the plurality of transport vehicles 1 in the transport facility 100 is preferably configured such that the distance between the second wall portion 14 and an end portion of the second bumper section 15 which end portion is on the travel-direction second side X2 is set larger than the protruding amount of the unit cover 72 from the end portion 12a of the first bumper section 12 on the travel-direction first side X1. Hereby, even in a case where the transport vehicles 1 collide with each other on the travel path 10, the first bumper section 12 of a preceding transport vehicle 1 directly collides with the second bumper section 15 of a following transport vehicle 1, so that it is possible to protect the unit cover 72 and the information communication unit 2 stored in the unit cover 72 from impact. Note that the vehicle body 4 may not necessarily include the first bumper section 12 and the second bumper section 15.

(2) The above embodiment has described, as an example, the configuration in which the information communication unit 2 is detachably attached to the first wall portion 11, but the present invention is not limited to this. The information communication unit 2 may be detachably attached to the second wall portion 14, for example. Alternatively, the information communication unit 2 may be detachably attached to the connecting section 71c of the cover main body 71.

(3) The above embodiment has described, as an example, the configuration in which the obstacle sensor 16 configured to detect an obstacle on the travel-direction second side X2 is attached to the second wall portion 14, but the present invention is not limited to this. The obstacle sensor 16 can be attached to the connecting section 71c of the cover main body 71, or the like, instead of the second wall portion 14, for example.

(4) The above embodiment has described, as an example, the configuration in which the information communication unit 2 is disposed within the region S defined by the first-bumper-section outer edge 12b and the first wall portion 11 as viewed vertically, but the present invention is not limited to this. The information communication unit 2 may be disposed to protrude in the width direction Y from the region S defined by the first-bumper-section outer edge 12b and the first wall portion 11. This also applies to the unit cover 72 covering the information communication unit 2.

(5) The above embodiment has described, as an example, the configuration in which the power feeding connector 17 is disposed to face any direction except the upper side, but the present invention is not limited to this. The power feeding connector 17 may be disposed to face the upper side. In the above embodiment, the power feeding connector 17 is supported on the first wall portion 11 via the auxiliary bracket 42 independently from the information communication unit 2, but the present invention is not limited to this. The power feeding connector 17 may be supported on the support member 25 of the information communication unit 2, for example. As such, the power feeding connector 17 may be supported on the first wall portion 11, integrally with the information communication unit 2.

(6) Note that the configurations disclosed in the above embodiment can be applied in combination with the configurations disclosed in other embodiments (including combinations of the embodiments described as the other embodiments) as long as no inconsistency occurs. In terms of other configurations, the embodiment disclosed in the present specification is also just an example in all respects. Accordingly, various modifications can be made appropriately as far as it does not deviate from the scope of this disclosure.

### Overview of Embodiments

The following describes the overview of the transport vehicle described above.

A transport vehicle according to this disclosure is a transport vehicle for transporting an article and includes: a travel unit configured to travel; a vehicle body held by the travel unit and including a storage section configured to store the article; and an information communication unit. The vehicle body includes: a first wall portion facing the storage section from a first side in a travel direction of the travel unit which first side is one side in the travel direction; and a first bumper section disposed to project toward the first side in the travel direction from the first wall portion. The information communication unit includes: a sensor configured to detect motion of the vehicle body; a communications device configured to communicate with at least the travel unit; and a recording device configured to store detection data from the sensor and acquisition data acquired by the communications device. The information communication unit is detachably attached to the first wall portion and disposed, in the travel direction, between the first wall portion and an end portion of the first bumper section which end portion is on the first side in the travel direction.

In this configuration, since the transport vehicle includes the information communication unit, the transport vehicle can acquire vehicle information on the motion of the vehicle body, the state of the travel unit, or the like as data as needed and store the vehicle information. Accordingly, it is possible to easily collect the vehicle information on the transport vehicle.

In addition, in this configuration, since such an information communication unit is detachably attached to the first wall portion for which an operator relatively easily performs work, it is selectable whether or not the information communication unit is attached to the transport vehicle, and it is also possible to reduce differences between transport vehicles in terms of components to be used in a manufacturing process of the transport vehicles and in terms of components constituting the transport vehicles, depending on whether or not the transport vehicles include the information communication unit. In addition, it is possible to easily attach the information communication unit to the transport vehicle after the use of the transport vehicle is started, and in a case where the information communication unit has a malfunction or the like, it is also possible to easily detach the information communication unit. This accordingly makes it possible to improve maintainability of the transport vehicle.

Besides, in this configuration, the information communication unit is disposed inward of (closer to the first wall portion than) the end portion of the first bumper section which end portion is on the first side in the travel direction. This accordingly makes it possible to protect the information communication unit from impact or the like.

Here, the vehicle body may include: a second wall portion facing the storage section from a second side in the travel direction which second side is opposite to the first side in the travel direction; and a second bumper section disposed to project toward the second side in the travel direction from the second wall portion, and the transport vehicle may further include an obstacle sensor attached to the second wall portion and configured to detect an obstacle on the second side in the travel direction, the second side in the travel direction being forward of the obstacle sensor in the travel direction.

In this configuration, the information communication unit is attached to a side opposite to a side where the obstacle sensor is attached. Accordingly, the first wall portion and the second wall portion can be effectively utilized. In addition, in this configuration, it is possible to easily downsize the vehicle body in comparison with a case where the information communication unit and the obstacle sensor are both attached to the first wall portion, for example.

The information communication unit may be disposed within a region defined by an outer edge of the first bumper and the first wall portion as viewed vertically.

In this configuration, the information communication unit is disposed inward of (closer to the first wall portion than) the outer edge of the first bumper section, and therefore, in a case where the transport vehicle collides with another transport vehicle, it is possible to more appropriately protect the information communication unit.

The transport vehicle may further include a power feeding connector attached to the first wall portion and including a feed terminal configured to supply electric power to the information communication unit, and the power feeding connector may be disposed to face any direction except an upper side.

With this configuration, even in a case where the information communication unit is not attached to the vehicle body, it is possible to prevent dust or the like from entering the power feeding connector.

The transport vehicle according to this disclosure should be able to achieve at least one of the above effects.

What is claimed is:

1. A transport vehicle for transporting an article, comprising:
a travel unit configured to travel;
a vehicle body held by the travel unit and including a storage section configured to store the article; and
an information communication unit,
wherein the vehicle body comprises:
a first wall portion facing the storage section from a first side in a travel direction of the travel unit which first side is one side in the travel direction; and
a first bumper section disposed to project toward the first side in the travel direction from the first wall portion,
wherein the information communication unit comprises:
a sensor configured to detect motion of the vehicle body;
a communications device configured to communicate with at least the travel unit; and
a recording device configured to store detection data from the sensor and acquisition data acquired by the communications device, and
wherein the information communication unit is detachably attached to the first wall portion and disposed, in the travel direction, between the first wall portion and an end portion of the first bumper section which end portion is on the first side in the travel direction.

2. The transport vehicle according to claim 1, wherein:
the vehicle body comprises:
a second wall portion facing the storage section from a second side in the travel direction which second side is opposite to the first side in the travel direction; and
a second bumper section disposed to project toward the second side in the travel direction from the second wall portion,
the transport vehicle further comprises an obstacle sensor attached to the second wall portion and configured to detect an obstacle on the second side in the travel direction, and
the second side in the travel direction is forward of the obstacle sensor in the travel direction.

3. The transport vehicle according to claim 1, wherein:
the information communication unit is disposed within a region defined by an outer edge of the first bumper and the first wall portion as viewed vertically.

4. The transport vehicle according to claim 1, further comprising:
a power feeding connector attached to the first wall portion and comprising a feed terminal configured to supply electric power to the information communication unit, and
wherein the power feeding connector is disposed to face any direction except an upper side.
